(19) United States
(12) Patent Application Publication
(10) Pub. No.: US 2025/0393440 A1
(43) Pub. Date: Dec. 25, 2025

(54) WINDOW MEMBER, DISPLAY DEVICE HAVING THE SAME, AND ELECTRONIC DEVICE INCLUDING THE SAME

(71) Applicant: Samsung Display Co., Ltd., Yongin-si (KR)

(72) Inventors: Byoung Yul SHIM, Yongin-si (KR); KANG DUK CHOI, Yongin-si (KR); HYUNCHUL KIM, Yongin-si (KR); HYUN CHUL JUNG, Yongin-si (KR); Beomgyu CHOI, Yongin-si (KR)

(21) Appl. No.: 19/232,722

(22) Filed: Jun. 9, 2025

(30) Foreign Application Priority Data
Jun. 25, 2024 (KR) 10-2024-0083186
Jun. 27, 2024 (KR) 10-2024-0084846

(51) Int. Cl. H10K 59/80

(52) U.S. Cl. CPC H10K 59/872

(57) ABSTRACT

A window member according to an embodiment may include a flat area that extends in a first direction and a second direction and is substantially flat, and a curved area that extends from the flat area and has a curved shape along a third direction perpendicular to the first direction and the second direction. The flat area may have a first thickness along the third direction, and the curved area may have a second thickness at a first point of the curved area where the thickness direction perpendicular to the tangent line to the outline of the curved area forms a first angle with the third direction, and the second thickness may be smaller than the first thickness.

### CROSS-REFERENCE TO RELATED APPLICATION

The present application claims priority to and the benefit of Korean Patent Application No. 10-2024-0084846, filed on Jun. 27, 2024, in the Korean Intellectual Property Office, and Korean Patent Application No. 10-2024-0083186, filed on Jun. 25, 2024, in the Korean Intellectual Property Office, the entire content of which is hereby incorporated by reference.

### BACKGROUND

### 1. Field

Embodiments of the present disclosure relate to a window member, a display device having the same, and an electronic device including the same.

### 2. Description of the Related Art

Display devices such as light emitting devices and liquid crystal displays are applied to electronic devices such as smart phones, mobile phones, and multimedia terminals. Because display devices, for example, the screens of display devices are parts exposed by electronic devices to the outside, display devices are elements in designs of electronic devices.

In general, the screens of display devices are flat. Recently, as flexible display devices have been developed, the screens are not limited to flat surfaces but may be formed having curved surfaces. For example, when the edge of a display device is formed to have a curved surface, the screen-to-body ratio of the display device may be increased. Screen-to-body ratios reflect the technological levels of display devices, and at the same time, may play a role in costumer's choices of products.

### SUMMARY

Embodiments of the present disclosure provide a window member having curved areas, a display device having the same, and an electronic device including the same.

However, the effects of embodiments of the present disclosure are not limited to the above-described object, and they can be variously suitably expanded without departing from the technical spirit and scope of the present disclosure.

A window member according to an embodiment may include a flat area that extends in a first direction and a second direction and is substantially flat, and a curved area that extends from the flat area and has a curved shape along a third direction perpendicular (e.g., substantially perpendicular) to the first direction and the second direction. The flat area may have a first thickness along the third direction, and the curved area may have a second thickness at a first point of the curved area where the thickness direction perpendicular (e.g., substantially perpendicular) to the tangent line to the outline of the curved area forms a first angle with the third direction, and the second thickness may be smaller than the first thickness.

The first angle may be larger than about 0° and smaller than about 5°.

The curved area may have a third thickness at a second point of the curved area where the thickness direction perpendicular (e.g., substantially perpendicular) to the tangent line to the outline of the curved area forms a second angle with the third direction. The third thickness may be larger than the second thickness.

The second angle may be larger than about 75° and smaller than about 90°.

The thickness of the curved area may gradually increase from the first point to the second point.

The curved area may extend along one side of the flat area.

The third thickness may be substantially equal to or smaller than the first thickness.

The second thickness may range from about 0.980 times to about 0.999 times the first thickness.

The curved area may be at a corner of the flat area.

The curved area may have a curved shape along the first direction and the second direction.

The third thickness may be larger than the first thickness.

The second thickness may range from about 0.980 times to about 0.999 times the first thickness, and the third thickness may range from about 1.01 times to about 1.13 times the first thickness.

The thickness of the curved area measured from a plane perpendicular (e.g., substantially perpendicular) to the third direction may be a minimum thickness at a point where the thickness direction forms a third angle with the first direction, and the third angle may be about 40° to about 50°.

A display device according to an embodiment may include a display panel that includes a first display area that extends in a first direction and a second direction, a second display area being on a side of the first display area and having a curved shape along a third direction perpendicular (e.g., substantially perpendicular) to the first direction and the second direction, and a third display area being at a corner of the first display area and having a curved shape along the first direction, the second direction, and the third direction, a window member that includes a flat area that corresponds to the first display area, a first curved area that corresponds to the second display area, and a second curved area that corresponds to the third display area, and an adhesive member being between the display panel and the window member. The flat area of the window may have a first thickness, and the second curved area may have a second thickness at a first point of the second curved area where the thickness direction perpendicular (e.g., substantially perpendicular) to the tangent line to the outline of the window forms a first angle with the third direction, and the second thickness may be smaller than the first thickness.

An electronic device according to an embodiment may a display module including a display device; and a processor coupled to the display module and configured to control the display module to display an image. The display device may include a display panel that includes a first display area that extends in a first direction and a second direction, a second display area being on a side of the first display area and having a curved shape along a third direction perpendicular (e.g., substantially perpendicular) to the first direction and the second direction, and a third display area being at a corner of the first display area and having a curved shape along the first direction, the second direction, and the third direction; a window member that includes a flat area that corresponds to the first display area, a first curved area that corresponds to the second display area, and a second curved area that corresponds to the third display area; and an adhesive member being between the display panel and the window member. The flat area of the window may have a first thickness, the second curved area may have a second thickness at a first point of the second curved area where the thickness direction perpendicular (e.g., substantially perpendicular) to the tangent line to the outline of the window forms a first angle with the third direction, and the second thickness may be smaller than the first thickness.

According to embodiments of the present disclosure, a window member has curved areas, a display device includes the window member, and an electronic device includes the display device.

However, effects of embodiments of the present disclosure are not limited to the above-described effects, and it is apparent that they can be variously suitably expanded without departing from the spirit and scope of the present disclosure.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic perspective view of a display device according to an embodiment.

FIG. 2 is a plan view of the display device according to an embodiment.

FIG. 3 is a schematic cross-sectional view of the display module of FIG. 1 taken along line A-A′.

FIG. 4 is a schematic cross-sectional view of the display module of FIG. 1 taken along line B-B′.

FIG. 5 is a schematic cross-sectional view of a display panel according to an embodiment.

FIG. 6 is a perspective view of a window of the display device according to an embodiment.

FIG. 7 is a view taken along line I-I′ of FIG. 6.

FIG. 8 is a view taken along line II-II′ of FIG. 6.

FIG. 9 is a view taken along line III-III′ of FIG. 6.

FIG. 10 is a view taken along line IV-IV′ of FIG. 6.

FIGS. 11 and 12 are cross-sectional views sequentially illustrating a method of manufacturing a window for a display device according to an embodiment.

FIG. 13 is an enlarged view of a partial area AR of FIG. 12.

FIG. 14 is a view conceptually illustrating forces which are applied to the window during a method of manufacturing the widow for a display device according to an embodiment.

FIG. 15 is a block diagram of an electronic device according to an embodiment.

FIGS. 16 to 18 are schematic views of electronic devices according to various embodiments.

### DETAILED DESCRIPTION

In the following detailed description, only certain embodiments of the present disclosure have been shown and described, simply by way of illustration. The present disclosure can be variously suitably implemented and is not limited to the following embodiments.

The drawings and description are to be regarded as illustrative in nature and not restrictive. Like reference numerals designate like elements throughout the specification.

Further, the accompanying drawings are provided to help to easily understand embodiments disclosed in the present specification, and the technical spirit disclosed in the present specification is not limited by the accompanying drawings, and it will be appreciated that the present disclosure includes all of the modifications, equivalent matters, and substitutes included in the spirit and the technical scope of the present disclosure.

In embodiments, the size and thickness of each configuration shown in the drawings may be arbitrarily shown for understanding and ease of description, but the present disclosure is not limited thereto. In the drawings, the thickness of layers, films, panels, regions, and/or the like, may be exaggerated for clarity. In the drawings, the thicknesses of layers, films, panels, regions, and/or the like, may be exaggerated for clarity.

Further, it will be understood that when an element such as a layer, film, region, or substrate is referred to as being “on” another element, it can be directly on the other element or intervening elements may also be present. In embodiments, when an element is referred to as being “directly on” another element, there are no intervening elements present. Further, when an element is “on” a reference portion, the element may be above or below the reference portion, and it does not necessarily mean that the element is “above” or “on” in a direction opposite to gravity.

In embodiments, unless explicitly described to the contrary, the words “include” and “comprise”, and variations such as “includes,” “including,” “comprises,” or “comprising”, will be understood to imply the inclusion of stated elements but not the exclusion of any other elements.

Further, in the entire specification, when it is referred to as “on a plane” or “in a plan view,” it means when a target part is viewed from above, and when it is referred to as “on a cross-section”, it may mean when the cross-section obtained by cutting a target part vertically is viewed from the side.

Further, throughout the specification, when it is referred to as “coupled” or “connected”, this does not only mean that two or more constituent elements are directly coupled or connected, but may mean that two or more constituent elements are indirectly coupled or connected through another constituent element, are physically coupled or connected, electrically coupled or connected, or are integrated even though two or more constituent elements are referred as different names depending on a location and a function.

Hereinafter, various embodiments and modifications will be described in detail with reference to the drawings.

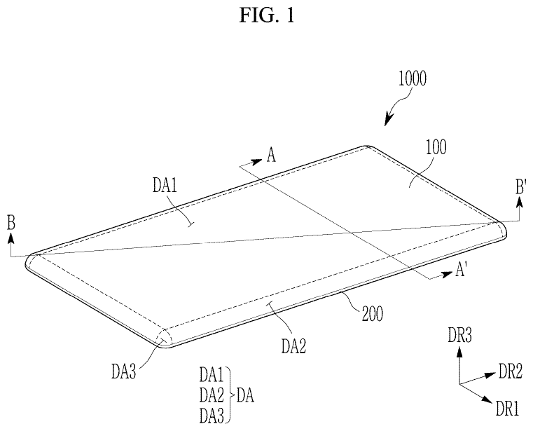

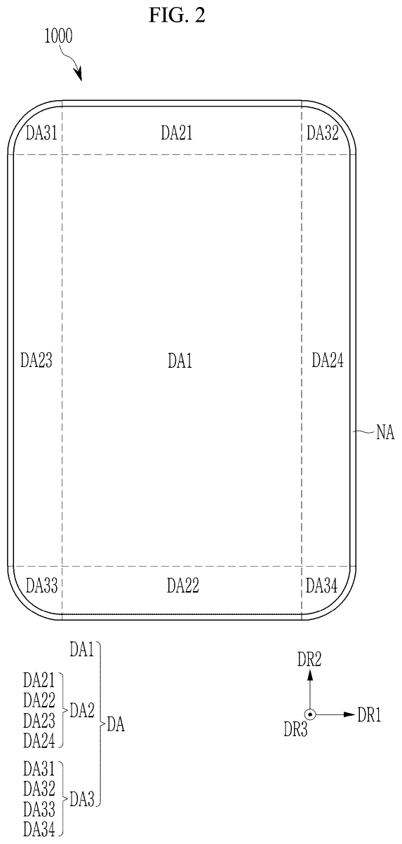

Referring to FIGS. 1 and 2, a display device 1000 according to an embodiment will be described. FIG. 1 is a schematic perspective view of the display device 1000 according to an embodiment, and FIG. 2 is a plan view of the display device 1000 according to an embodiment.

Referring to FIG. 2 together with FIG. 1, the display device 1000 according to an embodiment may be applied to an electronic device such as a smart phone, a mobile phone, a tablet PC, a multimedia player, and/or a game console.

The display device 1000 may provide a screen on which images are displayed in the electronic device.

The display device 1000 may include a display module 100 and a housing 200.

The display module 100 may provide a screen on which images are displayed. The housing 200 may be referred to as a set frame, and may hold the display module 100.

In the internal space defined by the display module 100 and the housing 200, various suitable components constituting the electronic device may be included. For example, a processor, a memory, a battery, a driver, a camera, a speaker, a microphone, a receiver, a communication module, sensors, and so on may be included inside the electronic device.

The display module 100 of the display device 1000 may include a display area DA, and the display area DA may include a first display area DA1 that is on the front, second display areas DA2 that are on the sides of the first display area DA1, and third display areas DA3 that are between the second display areas DA2 and are at the corners of the first display area DA1.

The second display areas DA2 and the third display areas DA3 may be referred to as side display areas and corner display areas, respectively.

The display module 100 of the display device 1000 may include non-display areas NA outside the second display areas DA2 and the third display areas DA3.

The first display area DA1 may be at the center in the display device 1000, and may occupy most of (e.g., a majority of) the screen. The first display area DA1 may be a flat area. The second display areas DA2 and the third display areas DA3 may surround the first display area DA1. The second display areas DA2 and the third display areas DA3 may be curved display areas.

The first display area DA1 may occupy the widest area in the entire display area DA. The first display area DA1 may be a substantially flat screen. In a plan view of the display device 1000 as seen from the front, the first display area DA1 may be an overall rectangular shape (e.g., a generally rectangular shape) having four sides that extend along a first direction DR1 and a second direction DR2; however, embodiments are not limited thereto.

The corners of the first display area DA1 may be sharp as shown in the drawings, but may also be rounded. Each of the four sides of the first display area DA1 may be parallel (e.g., substantially parallel) with the first direction DR1 or the second direction DR2.

The second display areas DA2 may include a first sub display area DA21, a second sub display area DA22, a third sub display area DA23, and a four sub display area DA24 that extend in directions parallel (e.g., substantially parallel) with the first direction DR1 or the second direction DR2.

The sub display areas DA21, DA22, DA23, and DA24 of the second display areas DA2 may about the four sides of first display area DA1.

The first sub display area DA21 and the second sub display area DA22 may extend in parallel (e.g., substantially in parallel) with the first direction DR1, and may face each other with the first display area DA1 therebetween. The third sub display area DA23 and the four sub display area DA24 may extend in parallel (e.g., substantially in parallel) with the second direction DR2, and may face each other with the first display area DA1 therebetween.

Each of the sub display areas DA21, DA22, DA23, and DA24 of the second display area DA2 may have a curved shape along a direction parallel (e.g., substantially parallel) with a third direction DR3 from the first display area DA1, and may form a curved screen. The curvature of each of the sub display areas DA21, DA22, DA23, and DA24 of the second display areas DA2 may be constant (e.g., substantially constant) regardless of locations, or may be different depending on locations.

Each of the sub display areas DA21, DA22, DA23, and DA24 of the second display areas DA2 may have a shape roughly similar to a portion (e.g., ¼) of the side surface of a curved-surface column such as a cylinder or an elliptical column. Each of the sub display areas DA21, DA22, DA23, and DA24 of the second display areas DA2 may have a single curved surface.

The third display areas DA3 may be at the four corners of the display device 1000. Each of the third display areas DA3 may be between two adjacent areas of the sub display areas DA21, DA22, DA23, and DA24.

The third display areas DA3 may include a fifth sub display area DA31, a sixth sub display area DA32, a seventh sub display area DA33, and an eighth sub display area DA34.

The fifth sub display area DA31 of the third display areas DA3 may be between the first sub display area DA21 and the third sub display area DA23 of the second display areas DA2, and the sixth sub display area DA32 of the third display areas DA3 may be between the first sub display area DA21 and the four sub display area DA24 of the second display areas DA2, and the seventh sub display area DA33 of the third display areas DA3 may be between the second sub display area DA22 and the third sub display area DA23 of the second display areas DA2, and the eighth sub display area DA34 of the third display areas DA3 may be between the second sub display area DA22 and the four sub display area DA24 of the second display areas DA2.

Each of the sub display areas DA31, DA32, DA33, and DA34 of the third display areas DA3 may be a curved surface, and may form a curved screen, and the curvature of each of the sub display areas DA31, DA32, DA33, and DA34 of the third display areas DA3 may be constant (e.g., substantially constant) regardless of the locations on the curved surface, or may be different depending on the locations on the curved surface.

The curved shape of the third display areas DA3 may be different from the curved shape of the second display areas DA2. Each third display area DA3 may have a shape roughly similar to a portion (e.g., ⅛) of a curved-surface body such as a sphere or an ellipsoid.

Each of the sub display areas DA31, DA32, DA33, and DA34 of the third display areas DA3 may have a curved shape along the first direction DR1 and the second direction DR2, as well as a curved shape along a direction parallel (e.g., substantially parallel) with the third direction DR3. Each of the sub display areas DA31, DA32, DA33, and DA34 of the third display areas DA3 may have a double curved surface (e.g., a surface having at least two different curves).

As the display device 1000 is seen from the front, a combination of the entire first display area DA1 and at least some of the second display areas DA2 and the third display areas DA3 may be recognized as an overall rectangular (e.g., generally rectangular) screen having rounded corners. The housing 200 may be invisible or almost invisible (e.g., transparent or substantially transparent), and a substantially bezel-less electronic device having a screen-to-body ratio of 1 or nearly 1 may be implemented.

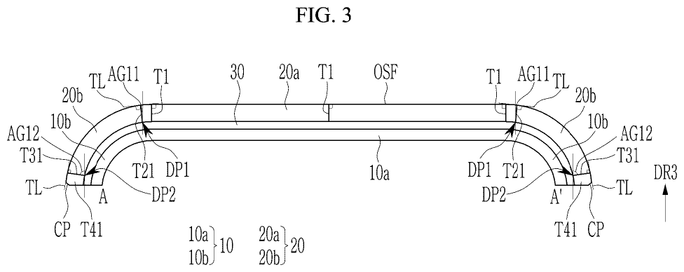

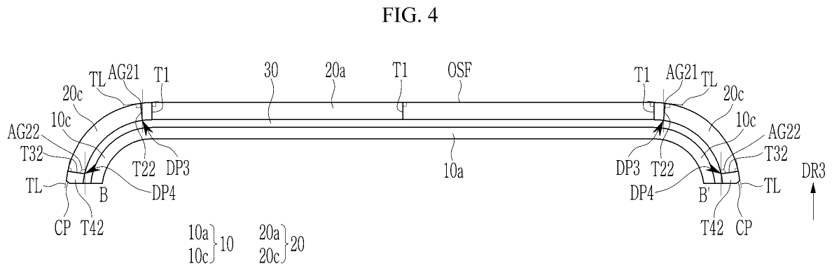

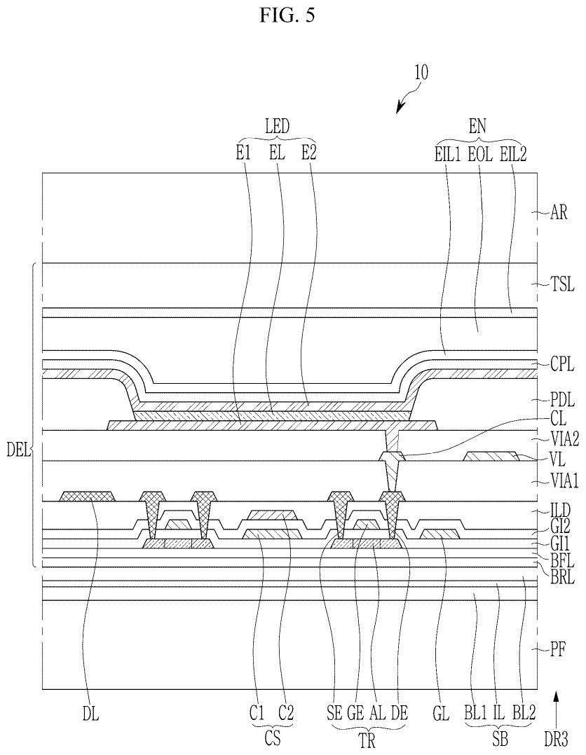

The display module 100 of the display device 1000 according to an embodiment will be described in more detail with reference to FIGS. 3 to 5 together with FIGS. 1 and 2. FIG. 3 is a schematic cross-sectional view of the display module 100 of FIG. 1 taken along line A-A′, and FIG. 4 is a schematic cross-sectional view of the display module 100 of FIG. 1 taken along line B-B′. FIG. 5 is a schematic cross-sectional view of a display panel 10 according to an embodiment.

Referring to FIGS. 3 and 4, the display module 100 of the display device 1000 according to an embodiment may include the display panel 10, a window 20, and an adhesive member 30.

In the display device 1000, images may be displayed by the display panel 10, and the window 20 may transmit the images displayed on the display panel 10 while covering the display panel 10.

The display panel 10 may be flexible in at least a portion thereof.

The display panel 10 may include a first display portion 10a that corresponds to the first display area DA1 of the display device 1000, second display portions 10b that corresponds to the second display areas DA2, and third display portions 10c that corresponds to the third display areas DA3.

The first display portion 10a of the display panel 10 may be at the center of the display panel 10, and may be a roughly flat area.

The second display portions 10b and third display portions 10c of the display panel 10 may surround the first display portion 10a, and may have a curved shape.

The whole of the first display portion 10a of the display panel 10 may correspond to the first display area DA1. The second display portions 10b and third display portions 10c of the display panel 10 may correspond to mostly the second display areas DA2 and the third display areas DA3, but may also correspond to the non-display areas NA outside the second display areas DA2 and the third display areas DA3.

The window 20 may be a kind of cover to protect the display panel 10 from external impacts. The window 20 may serve as a supporting member to maintain the curved state of the display panel 10. The window 20 may be made of a transparent and hard material such as glass and/or plastic such that users can see images which are displayed on the screen of the display panel 10.

The window 20 may include a flat area 20a that corresponds to the first display area DA1 of the display device 1000, first curved areas 20b that extend from the flat area 20a and correspond to the second display areas DA2, and second curved areas 20c that extend from the flat area 20a and correspond to the third display areas DA3.

The flat area 20a of the window 20 may extend in the first direction DR1 and the second direction DR2 and may be a substantially flat surface and may be flat, similar to the first display area DA1.

The first curved areas 20b of the window 20 may be on the sides of the flat area 20a of the window 20 and may have a curved shape along a direction parallel (e.g., substantially parallel) with the third direction DR3, similar to the second display areas DA2. Each of the first curved areas 20b of the window 20 may have a single curved surface.

The second curved areas 20c of the window 20 may be at the corners of the flat area 20a of the window 20 and be between the first curved areas 20b of the window 20, similar to the third display areas DA3. The second curved areas 20c of the window 20 may have curved shapes along the first direction DR1 and the second direction DR2, as well as curved shapes along a direction parallel (e.g., substantially parallel) with the third direction DR3. Each of the second curved areas 20c of the window 20 may have a double curved surface (e.g., a surface having at least two different curves).

In a cross-sectional view taken along a direction parallel (e.g., substantially parallel) with the third direction DR3 perpendicular (e.g., substantially perpendicular) to the surface of the flat area 20a of the window 20, the centers of curvature of the first curved areas 20b of the window 20 may partially coincide with the centers of curvature of the second display portions 10b of the display panel 10, and may partially not coincide with them.

The window 20 may include concave portions CP at the edges, and the concave portions CP may be formed at portions where air gaps that are used during the process of manufacturing the window 20 end, by compression of a mold. The concave portions CP may not be present in the first curved areas 20b of the window 20, and may be present only in the second curved areas 20c.

In a cross-sectional view taken along a direction parallel (e.g., substantially parallel) with the third direction DR3, the width of the portions of the edges of the window 20 where the concave portions CP have been formed may be within 2% of the overall width of the first curved areas 20b of the window 20.

The thickness of the window 20 may differ depending on the locations.

The flat area 20a of the window 20 may have a first thickness T1.

The thicknesses of the first curved areas 20b of the window 20 may increase as it goes from the flat area 20a toward the concave portions CP of the window 20.

The thicknesses of the first curved areas 20b may be thicknesses measured in directions perpendicular (e.g., substantially perpendicular) to the tangent lines TL to the outer surface OSF of the window 20.

The first curved areas 20b of the window 20 may have a second thickness T21 at first points DP1 which are the interfaces with the flat area 20a where the curved surfaces start, and may have a third thickness T31 at second points DP2 adjacent to the edge of the window 20 except for the concave portions CP. The third thickness T31 may be larger than the second thickness T21.

The thickness direction of each first point DP1, e.g., the direction perpendicular (e.g., substantially perpendicular) to the tangent line TL to the outer surface OSF at the first point DP1 may form an angle AG11 with a direction parallel (e.g., substantially parallel) with the third direction DR3, and the angle AG11 may be larger than about 0° and smaller than about 5°, and may be, for example, larger than about 0° and smaller than about 3°.

The thickness direction of each second point DP2, e.g., the direction perpendicular (e.g., substantially perpendicular) to the tangent line TL to the outer surface OSF at the second point DP2 may form an angle AG12 with a direction parallel (e.g., substantially parallel) with the third direction DR3, and the angle AG12 may be larger than about 75° and smaller than about 90°, and may be, for example, larger than about 80° and smaller than about 90°.

At the edges of the first curved areas 20b of the window 20, the first curved areas 20b of the window 20 may have a fourth thickness T41.

The thicknesses of the first curved areas 20b of the window 20 may gradually increase from the first points DP1 toward the second points DP2.

The second thickness T21 may be smaller than the first thickness T1, and the third thickness T31 may be substantially equal to or smaller than the first thickness T1. The fourth thickness T41 may be smaller than the first thickness T1.

The second thickness T21 may range from about 0.980 times to about 0.999 times the first thickness T1.

When the window 20 is formed into a curved shape, tensile forces are applied to the first curved areas 20b of the window 20. Therefore, the thicknesses of the first curved areas 20b of the window 20 may be minimal at the interfaces with the flat area 20a where the curved surfaces start, and increase toward the edge of the window 20. In an embodiment, the thicknesses at the edges of the first curved areas 20b of the window 20 may be slightly decreased by the concave portions CP which are formed at the edge of the window 20. However, the thicknesses of the edges of the first curved areas 20b of the window 20 may be larger than the second thickness T21 at the interfaces of the first curved areas 20b and flat area 20a of the window 20.

Similar to the first curved areas 20b of the window 20, the thicknesses of the second curved areas 20c of the window 20 may increase from the flat area 20a toward the concave portions CP of the window 20.

The thicknesses of the second curved areas 20c of the window 20 may be thicknesses measured in directions perpendicular (e.g., substantially perpendicular) to the tangent lines TL to the outer surface OSF of the window 20.

The second curved areas 20c of the window 20 may have a fifth thickness T22 at the interfaces with the flat area 20a where the curved surfaces start, e.g., at third points DP3, and may have a sixth thickness T32 at fourth points DP4 adjacent to the concave portions CP at the edge of the window 20. The sixth thickness T32 may be larger than the fifth thickness T22.

The thickness direction of each third point DP3, e.g., the direction perpendicular (e.g., substantially perpendicular) to the tangent line TL to the outer surface OSF at the third point DP3 may form an angle AG21 with a direction parallel (e.g., substantially parallel) with the third direction DR3, and the angle AG21 may be larger than about 0° and smaller than about 5°, and may be, for example, larger than about 0° and smaller than about 3°.

The thickness direction of each fourth point DP4, e.g., the direction perpendicular (e.g., substantially perpendicular) to the tangent line TL to the outer surface OSF at the fourth point DP4 may form an angle AG22 with a direction parallel (e.g., substantially parallel) with the third direction DR3, and the angle AG22 may be larger than about 75° and smaller than about 90°, and may be, for example, larger than about 80° and smaller than about 90°.

At the edges of the second curved areas 20c of the window 20, the second curved areas 20c of the window 20 may have a seventh thickness T42.

The thicknesses of the second curved areas 20c of the window 20 may gradually increase from the third points DP3 toward the fourth points DP4.

The fifth thickness T22 may be smaller than the first thickness T1, and the sixth thickness T32 may be larger than the first thickness T1. The seventh thickness T42 may be larger than the first thickness T1, and the sixth thickness T32 may be larger than the seventh thickness T42.

The fifth thickness T22 may range from about 0.980 times to about 0.999 times the first thickness T1, and the sixth thickness T32 may range from about 1.01 times to about 1.13 times the first thickness T1.

The seventh thickness T42 may range from about 1.002 times to about 1.0043 times the first thickness T1.

When the window 20 is formed into a curved shape, tensile forces and compressive forces may be applied to the second curved areas 20c of the window 20, depending on the locations. For example, because tensile forces are applied to the portions of the second curved areas 20c adjacent to the flat area 20a, and compressive forces are applied to the portions of the second curved areas 20c adjacent to the edge of the window 20, the thicknesses of the second curved areas 20c of the window 20 may be minimal at the interfaces with the flat area 20a where the curved surfaces start, and increase toward the edge of the window 20, and be larger than the thickness of the flat area 20a. The thicknesses of the second curved areas 20c of the window 20 at the edges may be slightly decreased by the concave portions CP which are formed at the edge of the window 20; however, the thicknesses at the edges of the second curved areas 20c of the window 20 may be larger than the thickness of the flat area 20a of the window 20.

The display device 1000 according to an embodiment may include the window 20 whose thickness is relatively small at the portions of the curved areas 20a adjacent to the flat area, gradually increases, and is relatively large at the edge portions of the curved areas because tensile force and compressive force have been applied when the window 20 has been formed into a curved shape. As described above, the thickness of the window 20 may differ depending on the locations of the curved areas 20b and 20c of the window 20, and the thickness may increase from the portions close to the flat area 20a toward the edge. Therefore, it is possible to prevent or reduce occurrence of breakage, buckling, and burrs during the window forming process. Accordingly, the display device 1000 may include the window 20 having a smooth inner surface covering the display panel 10. Therefore, it is possible to prevent or reduce degradation of the image quality of images passing through the window 20 not only in the flat display area DA1 but also in the curved display areas DA2 and DA3.

The display panel 10 may be attached to the window 20 by the adhesive member 30. The adhesive member 30 may include an adhesive such as an optically clear adhesive (OCA) and/or an optically clear resin (OCR), but embodiments are not limited thereto.

The first display portion 10a of the display panel 10 may be attached to the flat area 20a of the window 20, and the second display portions 10b and third display portions 10c of the display panel 10 may be attached to the first curved areas 20b and second curved areas 20c of the window 20.

Referring to FIG. 5, the general stack structure of the display panel 10 will be described. The cross-sectional view shown in FIG. 5 may correspond to approximately one pixel area of the display panel 10.

The display panel 10 basically includes a substrate SB, transistors TR formed on the substrate SB, and light emitting diodes LED coupled to the transistors TR. The light emitting diodes LED may correspond to pixels.

The substrate SB may be a multi-layer including a first base layer BL1, an inorganic layer IL, and a second base layer BL2. The first and second base layers BL1 and BL2 may contain a polymer resin such as polyimide, polyamide, and/or polyethylene terephthalate.

A barrier layer BRL for preventing or reducing penetration of moisture, oxygen, and/or the like may be on the substrate SB. The barrier layer BRL may contain an inorganic insulating material (e.g., an inorganic electrically insulating material) such as silicon nitride (SiNₓ), silicon oxide (SiOₓ), and/or silicon oxynitride (SiOₓN_{y}), and may be a single layer or a multi-layer.

A buffer layer BFL may be on the barrier layer BRL. The buffer layer BFL may block or reduce penetration of impurities from the substrate SB when semiconductor layers are formed, thereby improving the characteristics of the semiconductor layers, and may flatten the surface of the substrate SB, thereby relieving the stress of semiconductor layers. The buffer layer BFL may contain an inorganic insulating material (e.g., an inorganic electrically insulating material) such as silicon nitride, silicon oxide, and/or silicon oxynitride, and may be a single layer or a multi-layer. The buffer layer BFL may contain amorphous silicon (Si).

Semiconductor layers AL for the transistors TR may be on the buffer layer BFL. The semiconductor layers AL may include first regions, second regions, and channel regions between those regions. The semiconductor layers AL may contain any one selected from amorphous silicon, polycrystalline silicon, and oxide semiconductors. For example, the semiconductor layers AL may contain low-temperature polycrystalline silicon (LTPS), or may contain an oxide semiconductor material containing at least one selected from zinc (Zn), indium (In), gallium (Ga), and Tin (Sn). For example, the semiconductor layers AL may contain indium-gallium-zinc oxide (IGZO).

A first gate insulating layer GI1 may be on the semiconductor layers AL. The first gate insulating layer GI1 may contain an inorganic insulating material (e.g., an inorganic electrically insulating material) such as silicon nitride, silicon oxide, and/or silicon oxynitride, and may be a single layer or a multi-layer.

A first gate conductive layer which may include gate electrodes GE for the transistors TR, gate lines GL, first electrodes C1 for capacitors CS, and/or the like may be on the first gate insulating layer GI1. The first gate conductive layer may contain molybdenum (Mo), aluminum (AI), copper (Cu), titanium (Ti), and/or the like, and may be a single layer or a multi-layer.

A second gate insulating layer GI2 may be on the first gate conductive layer. The second gate insulating layer GI2 may contain an inorganic insulating material (e.g., inorganic electrically insulating material) such as silicon nitride, silicon oxide, and/or silicon oxynitride, and may be a single layer or a multi-layer.

A second gate conductive layer which may include second electrodes C2 for the capacitors CS and/or the like may be on the second gate insulating layer GI2. The second gate conductive layer may contain molybdenum (Mo), aluminum (AI), copper (Cu), titanium (Ti), and/or the like, and may be a single layer or a multi-layer.

An interlayer insulating layer ILD may be on the second gate insulating layer GI2 and the second gate conductive layer. The interlayer insulating layer ILD may contain an inorganic insulating material (e.g., an inorganic electrically insulating material) such as silicon nitride, silicon oxide, and/or silicon oxynitride, and may be a single layer or a multi-layer.

A first data conductive layer which may include first electrodes SE and second electrodes DE for the transistors TR, data lines DL, and the like may be on the interlayer insulating layer ILD. The first electrodes SE and the second electrodes DE may be coupled to the first regions and second regions of the semiconductor layers AL through contact holes in the insulating layers GI1, GI2, and ILD, respectively. The first electrodes SE or the second electrodes DE may be source electrodes, and the others of them may be drain electrodes. The first data conductive layer may contain aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like, and may be a single layer or a multi-layer.

A first polarization layer VIA1 may be on the first data conductive layer. The first polarization layer VIA1 may be an organic insulating layer (e.g., an organic electrically insulating layer). For example, the first polarization layer VIA1 may contain an organic insulating material (e.g., an organic electrically insulating material) such as a generally used polymer such as polymethylmethacrylate and/or polystyrene, a polymer derivative having a phenol-based group, an acryl-based polymer, an imide-based polymer, polyimide, a siloxane-based polymer, and/or the like.

A second data conductive layer which may include voltage lines VL, connection lines CL, and/or the like may be on the first polarization layer VIA1. The voltage lines VL may transfer voltages such as a driving voltage, a common voltage, an initialization voltage, a reference voltage, and/or the like. The connection lines CL may be coupled to the second electrodes DE of the transistors TR through contact holes in the first polarization layer VIA1. The second data conductive layer may contain aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and/or the like, and may be a single layer or a multi-layer.

A second polarization layer VIA2 may be on the second data conductive layer. The second polarization layer VIA2 may be an organic insulating layer (e.g., an organic electrically insulating layer). For example, the second polarization layer VIA2 may contain an organic insulating material (e.g., an organic electrically insulating material) such as a generally used polymer such as polymethylmethacrylate and/or polystyrene, a polymer derivative having a phenol-based group, an acryl-based polymer, an imide-based polymer, polyimide, a siloxane-based polymer, and/or the like.

First electrodes E1 of the light emitting diodes LED may be on the second polarization layer VIA2. The first electrodes E1 may be referred to as pixel electrodes. The first electrodes E1 may be coupled to the connection lines CL through contact holes in the second polarization layer VIA2. Therefore, the first electrodes E1 may be electrically coupled to the second electrodes DE of the transistors TR, thereby receiving data signals to control the luminance of the light emitting diodes LED. The transistors TR which are coupled to the first electrodes E1 may be driving transistors, or transistors electrically coupled to the driving transistors. The first electrodes E1 may be formed of a reflective conductive material (e.g., a reflective electrically conductive material) or a semi-transmissive conductive material (e.g., a semi-transmissive electrically conductive material), and may be formed of a transparent conductive material (e.g., a transparent electrically conductive material). The first electrodes E1 may contain a transparent conductive material such as indium tin oxide (ITO) and/or indium zinc oxide (IZO). The first electrodes E1 may contain a metal such as lithium (Li), calcium (Ca), aluminum (AI), silver (Ag), magnesium (Mg), and/or gold (Au), and/or a metal alloy.

A pixel definition layer PDL which may be an organic insulating layer (e.g., an organic electrically insulating layer) may be on the second polarization layer VIA2. The pixel define layer PDL may be referred to as a partition, and may have openings that overlap the first electrodes E1.

Emission layers EL of the light emitting diodes LED may be on the first electrodes E1. In addition to an emission layer EL, at least one selected from a hole injection layer, a hole transport layer, an electron transport layer, and an electron injection layer may be on each first electrode E1.

A second electrode E2 of the light emitting diodes LED may be on the emission layers EL. The second electrode E2 may be referred to as common electrodes. The second electrode E2 may be formed of a metal such as calcium (Ca), barium (Ba), magnesium (Mg), aluminum (Al), silver (Ag), and/or the like, and/or a metal alloy, having a low work function, so as to become thin layers, thereby having light transmittance. The second electrode E2 may contain a transparent conductive oxide such as indium tin oxide (ITO) and/or indium zinc oxide (IZO).

The first electrode E1, the emission layer EL, and the second electrode E2 of each pixel form a light emitting diode LED such as an organic light emitting diode. The first electrode E1 may be the anode of the light emitting diode LED, and the second electrode E2 may be the cathode of the light emitting diode LED.

A capping layer CPL may be on the second electrodes E2. The capping layer CPL may improve optical efficiency through a refractive index adjustment. The capping layer CPL may cover the second electrodes E2 entirely. The capping layer CPL may contain an organic insulating material (e.g., an organic electrically insulating material), and may contain an inorganic insulating material (e.g., an inorganic electrically insulating material).

An encapsulating layer EN may be on the capping layer CPL. The encapsulating layer EN may encapsulate the light emitting diodes LED, thereby preventing or reducing penetration of moisture and/or oxygen from the outside. The encapsulating layer EN may be a thin-film encapsulating layer including one or more selected from inorganic layers EIL1 and EIL2 and one or more organic layers EOL.

A touch sensor layer TSL including touch electrodes may be on the encapsulating layer EN. The touch electrodes may have a mesh shape having openings that overlap the light emitting diodes LED. An antireflective layer AR to reduce reflection of external light may be on the touch sensor layer TSL.

A display element layer DEL may include the layers between the substrate SB and the antireflective layer AR, and may include, for example, the transistors TR, the capacitors CS, and the light emitting diodes LED.

A protective film PF to protect the display panel 10 may be under the substrate SB. Further, a functional sheet including at least one selected from cushion layers, heat dissipation sheets, light shielding sheets, waterproof tape, and electromagnetic shielding layers may be under the protective film.

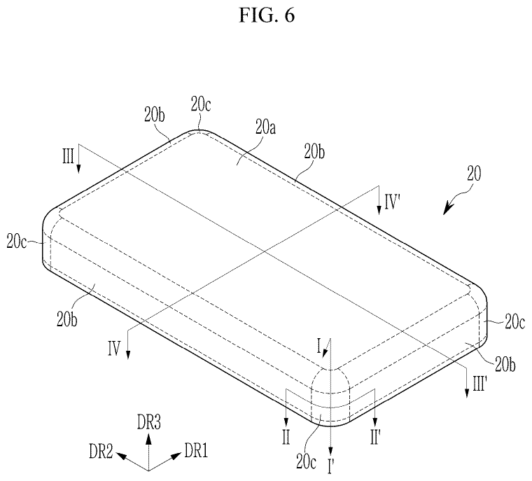

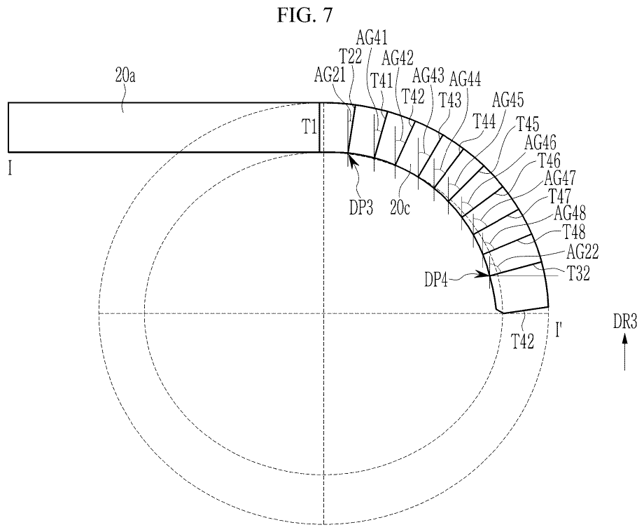

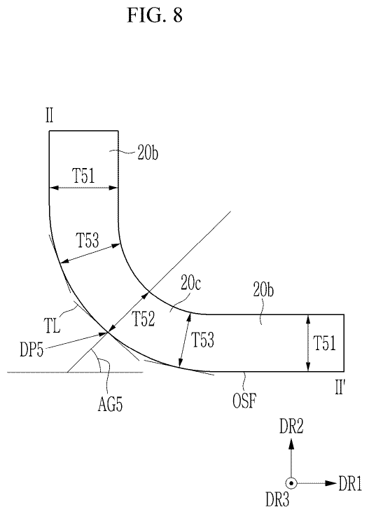

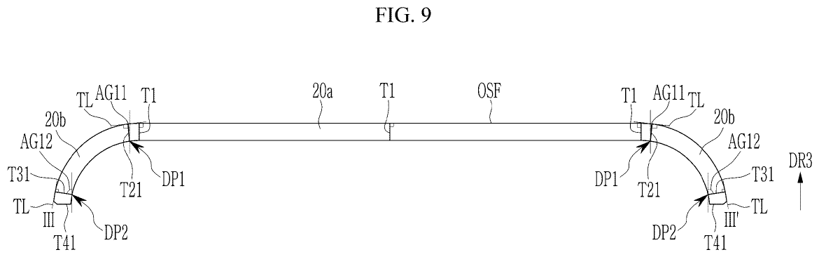

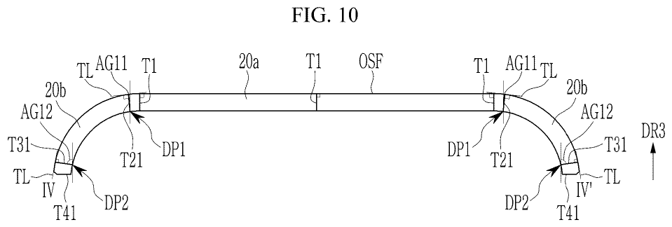

The window 20 of the display device according to an embodiment will be described in more detail with reference to FIGS. 6 to 10. FIG. 6 is a perspective view of the window 20 of the display device 1000 according to an embodiment, FIG. 7 is a view taken along line I-I′ of FIG. 6, FIG. 8 is a view taken along line II-II′ of FIG. 6, FIG. 9 is a view taken along line III-III′ of FIG. 6, and FIG. 10 is a view taken along line IV-IV′ of FIG. 6.

Referring to FIG. 7, the thicknesses of the second curved areas 20c of the window 20 may increase from the flat area 20a toward the concave portions CP of the window 20.

The center of curvature of the curved surface which is formed by the outer surfaces OSF of the second curved areas 20c of the window 20 and the center of curvature of the curved surface which is formed by the inner surfaces of the second curved areas 20c of the window 20 may not coincide with each other, and the centers of curvature of the curved surface which is formed by the inner surfaces of the second curved areas 20c may differ depending on the locations.

The second curved areas 20c of the window 20 may have a fifth thickness T22 at the interfaces with the flat area 20a where the curved surfaces start, e.g., at third points DP3, and may have a sixth thickness T32 at fourth points DP4 adjacent to the concave portions CP at the edge of the window 20. At the edges of the second curved areas 20c of the window 20, the second curved areas 20c of the window 20 may have a seventh thickness T42.

The thickness direction of each third point DP3, e.g., the direction perpendicular (e.g., substantially perpendicular) to the tangent line TL to the outer surface OSF at the third point DP3 may form an angle AG21 with a direction parallel (e.g., substantially parallel) with the third direction DR3, and the angle AG21 may be larger than about 0° and smaller than about 5°, and may be, for example, larger than about 0° and smaller than about 3°.

The thickness direction of each fourth point DP4, e.g., the direction perpendicular (e.g., substantially perpendicular) to the tangent line TL to the outer surface OSF at the fourth point DP4 may form an angle AG22 with a direction parallel (e.g., substantially parallel) with the third direction DR3, and the angle AG22 may be larger than about 75° and smaller than about 90°, and may be, for example larger than about 80° and smaller than about 90°.

The thicknesses of the second curved areas 20c of the window 20 may increase from the flat area 20a toward the concave portions CP of the window 20.

As the angles which the thickness directions of the second curved areas 20c of the window 20 at a plurality of points form with directions parallel (e.g., substantially parallel) with the third direction DR3 increase, the thicknesses of the second curved areas 20c of the window 20 at the plurality of points may increase. In embodiments, the thickness directions may be directions which are direction perpendicular (e.g., substantially perpendicular) to the tangent lines TL of the outer surfaces OSF of the second curved areas 20c of the window 20 and in which the thicknesses are measured.

As the angles AG41, AG42, AG43, AG44, AG45, AG46, AG47, and AG48 which the thickness directions of the second curved areas 20c at the individual points form with the third direction DR3 increase from the angle AG21 to the angle AG22, the thicknesses T41, T42, T43, T44, T45, T46, T47, and T48 at the individual locations may also increase.

The fifth thickness T22 may be smaller than the first thickness T1, and the sixth thickness T32 may be larger than the first thickness T1. The seventh thickness T42 may be larger than the first thickness T1, and the sixth thickness T32 may be larger than the seventh thickness T42.

The fifth thickness T22 may range from about 0.980 times to about 0.999 times the first thickness T1, and the sixth thickness T32 may range from about 1.01 times to about 1.13 times the first thickness T1.

The seventh thickness T42 may range from about 1.002 times to about 1.0043 times the first thickness T1.

The thicknesses T41, T42, T43, T44, T45, T46, T47, and T48 of the second curved areas 20c at the individual locations may have values between the fifth thickness T22 and the sixth thickness T32.

As described above, the second curved areas 20c of the window 20 may have a curved shape along the plane direction of the first direction DR1 and the second direction DR2 in which the flat area 20a extends, as well as a curved shape along a height direction parallel (e.g., substantially parallel) with the third direction DR3.

Referring to FIG. 8, on a plane perpendicular (e.g., substantially perpendicular) to the third direction DR3, the first curved areas 20b may have an eighth thickness T51, and the thicknesses T52 and T53 of the second curved areas 20c of the window 20 may be smaller than the eighth thickness T51 of the first curved areas 20b.

The thicknesses T52 and T53 of the second curved areas 20c of the window 20 may gradually decrease from portions adjacent to the first curved areas 20b toward fifth points DP5.

For example, the fifth points DP5 of the second curved areas 20c of the window 20 may have a ninth thickness T52, and some points between the first curved areas 20b and the fifth points DP5 may have a tenth thickness T53. The ninth thickness T52 may be smaller than the tenth thickness T53.

The ninth thickness T52 may be the minimum thickness of the second curved areas 20c measured from a plane perpendicular (e.g., substantially perpendicular) to the third direction DR3.

The thickness directions at the fifth points DP5, e.g., the directions perpendicular (e.g., substantially perpendicular) to the tangent lines TL to the outer surfaces OSF at the fifth points DP5 may form an angle AG5 with the first direction DR1, and the angle A5 may range from about 40° to about 50°, for example, from about 43° to about 47°.

When the window 20 is formed into a curved shape, tensile forces and compressive forces may be applied to the second curved areas 20c of the window 20, depending on the locations. For example, tensile forces may be applied to the portions of the second curved areas 20c adjacent to the flat area 20a, and compressive forces may be applied to the portions of the second curved areas 20c adjacent to the edge of the window 20, and the tensile forces may be largest at locations where they form an angle of about 45° with the first direction DR1 and the second direction DR2 on a plane which is formed by the first direction DR1 and the second direction DR2. Therefore, the ninth thickness T52 may be the minimum thickness of the second curved areas 20c measured from a plane perpendicular (e.g., substantially perpendicular) to the third direction DR3.

As described above, when the window 20 is formed into a cube shape, tensile forces and compressive forces may be applied to the second curved areas 20c of the window 20, depending on the locations. Therefore, the thicknesses of the second curved areas 20c of the window 20 may be minimal at the interfaces with the flat area 20a where the curved surfaces start, and increase toward the edge of the window 20, and be larger than the thickness of the flat area 20a. The thicknesses of the second curved areas 20c of the window 20 at the edges may be slightly decreased by the concave portions CP which are formed at the edge of the window 20; however, the thicknesses at the edges of the second curved areas 20c of the window 20 may be larger than the thickness of the flat area 20a of the window 20.

Referring to FIGS. 9 and 10, the first curved areas 20b of the window 20

which extend in parallel (e.g., substantially in parallel) with the first direction DR1 and the second direction DR2 and have a curved shape along the third direction DR3 may have the second thickness T21 at the first points DP1 which are the interfaces with the flat area 20a where the curved surfaces start, and may have the third thickness T31 at the second points DP2 adjacent to the edge of the window 20 except for the concave portions CP. The third thickness T31 may be larger than the second thickness T21.

The thickness direction of each first point DP1, e.g., the direction perpendicular (e.g., substantially perpendicular) to the tangent line TL to the outer surface OSF at the first point DP1 may form the angle AG11 with a direction parallel (e.g., substantially parallel) with the third direction DR3, and the angle AG11 may be larger than about 0° and smaller than about 5°, and may be, for example, larger than about 0° and smaller than about 3°.

The thickness direction of each second point DP2, e.g., the direction perpendicular (e.g., substantially perpendicular) to the tangent line TL to the outer surface OSF at the second point DP2 may form the angle AG12 with a direction parallel (e.g., substantially parallel) with the third direction DR3, and the angle AG12 may be larger than about 75° and smaller than about 90°, and may be, for example, larger than about 80° and smaller than about 90°.

At the edges of the first curved areas 20b of the window 20, the first curved areas 20b of the window 20 may have the fourth thickness T41.

The second thickness T21 may be smaller than the first thickness T1, and the third thickness T31 may be substantially equal to or smaller than the first thickness T1. The fourth thickness T41 may be smaller than the first thickness T1.

The second thickness T21 may range from about 0.980 times to about 0.999 times the first thickness T1.

Because tensile forces and compressive forces have been applied when the window 20 has been formed into a curved shape, the window 20 according to an embodiment may have thickness which is relatively small at the portions of the curved areas adjacent to the flat area 20a, gradually increases, and is relatively large at the edge portions of the curved areas. As described above, the thickness of the window 20 may differ depending on the locations of the curved areas 20b and 20c of the window 20, and the thickness may increase from the portions close to the flat area 20a toward the edge. Therefore, it is possible to prevent or reduce occurrence of breakage, buckling, and burrs during the window forming process.

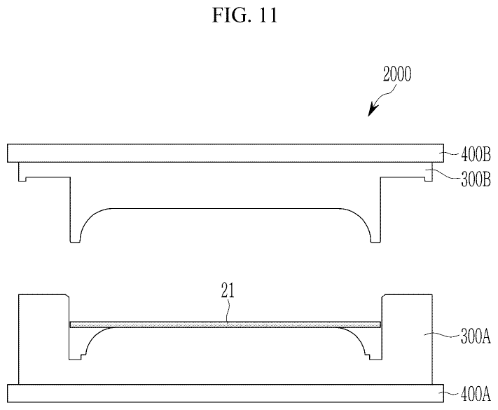

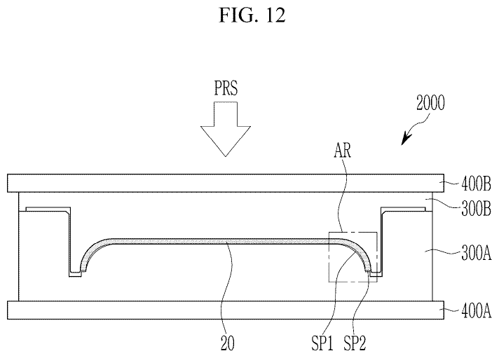

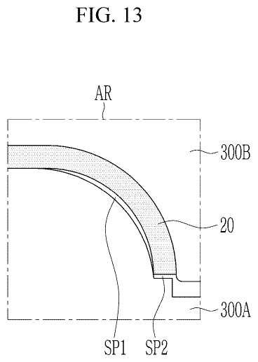

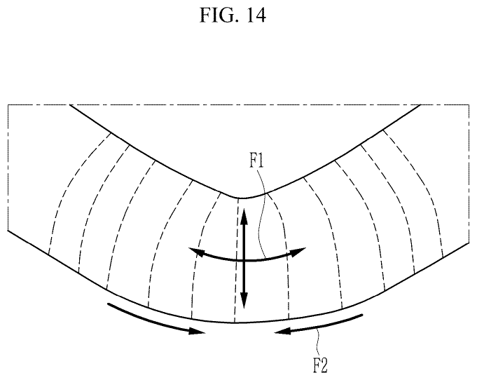

A method of manufacturing a window 20 for a display device 1000 according to an embodiment will be described with reference to FIGS. 11 to 14. FIGS. 11 and 12 are cross-sectional views sequentially illustrating a method of manufacturing a window for a display device according to an embodiment, and FIG. 13 is an enlarged view of a partial area of FIG. 12, and FIG. 14 is a view conceptually illustrating forces which are applied to the window during the method of manufacturing the widow for a display device according to an embodiment.

Referring to FIG. 11, a window forming apparatus 2000 may include a lower

mold 300A, an upper mold 300B, a lower heat source 400A attached to the lower mold 300A, and an upper heat source 400B attached to the upper mold 300B.

After an unformed flat window member 21 is prepared and provided between the lower mold 300A and upper mold 300B of the window forming apparatus 2000, the upper mold 300B may be moved such that the gap between the lower mold 300A and the upper mold 300B decreases.

As shown in FIG. 12, the window member 21 may be pressed (reference symbol “PRS”) such that at least some portions of the upper mold 300B and the lower mold 300A come into contact with the window member 21, and thermal energy may be supplied to the lower heat source 400A and the upper mold 300B such that a window 20 including a flat area 20a, first curved areas 20b, and second curved areas 20c is formed.

Referring to FIGS. 12 and 13, during the window forming process, a first gap area SP1 and a second gap area SP2 may be formed between the lower mold 300A and the window 20. The first curved areas 20b and second curved areas 20c of the window 20 may overlap the first gap area SP1 and the second gap area SP2, and the shapes of the lower mold 300A and the upper mold 300B may be formed such that the first gap area SP1 and the second gap area SP2 are maintained, thereby preventing or reducing occurrence of breakage, buckling, and burrs at the second curved areas 20c of the window 20 during the window forming process.

At the edge of the window 20 which is at the end of the first gap area SP1, concave portions CP may be formed.

Referring to FIG. 14, during the window forming process, because the portions where the second curved areas 20c are formed are formed so as to have curved surfaces along the first direction DR1 and the second direction DR2 which are plane directions, as well as curved surfaces along the third direction DR3 which is the height direction, tensile forces F1 may be applied to the portions adjacent to the flat area 20a and compressive forces F2 may be applied to the portions adjacent to the edge of the window 20.

An experimental example will be described with reference to Table 1. In the present experimental example, a window having a flat area 20a and curved areas 20b and 20c similar to the window 20 for the display device according to an embodiment was formed, and the thicknesses of the window at a second curved area having a double curved surface were measured and are shown in Table 1. The thicknesses of the window were measured from a cross section forming an angle of about 45° with the first direction DR1 and the second direction DR2.

In addition to the thickness of the flat area, the window thicknesses were measured at 8 locations (sequentially, Location 1, Location 2, Location 3, Location 4, Location 5, Location 6, Location 7, and Location 8) having substantially uniform intervals from the third point DP3 of the second curved area described above to the fourth point DP4. Location 1 is a location closest to the third point DP3, and Location 8 is a location closest to the fourth point DP4.

TABLE 1

| Location | Thickness (T) |
|---|---|
| Flat Area | 0.596 |
| Third Point | 0.595 |
| Location 1 | 0.602 |
| Location 2 | 0.609 |
| Location 3 | 0.611 |
| Location 4 | 0.616 |
| Location 5 | 0.618 |
| Location 6 | 0.622 |
| Location 7 | 0.630 |
| Location 8 | 0.638 |
| Fourth Point | 0.639 |

Referring to Table 1, it was determined that similar to the window 20 of the display device according to an embodiment, the thickness of the window differs depending on the locations and the thicknesses of the second curved areas of the window increase from the flat area toward the edge of the window. According to the window member for a display device having curved display areas according to an embodiment and the display device including the same, the window may have thickness which is relatively small at the portions of the curved areas adjacent to the flat area, gradually increases, and is relatively large at the edge portions of the curved areas, depending on the portions to which tensile forces and compressive forces are applied during the window forming process. Therefore, it is possible to prevent or reduce occurrence of breakage, buckling, and burrs during the window forming process, and because the display device 1000 may include the window 20 having a smooth inner surface covering the display panel 10, it is possible to prevent or reduce degradation of the image quality of images passing through the window 20 not only in the flat display area DA1 but also in the curved display areas DA2 and DA3.

The display device according to embodiments may be applied to various suitable electronic devices. An electronic device according to an embodiment may include the display device, and may further include modules and/or devices having additional functions other than the display device.

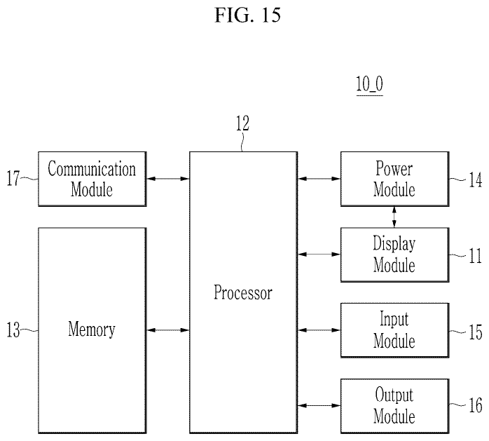

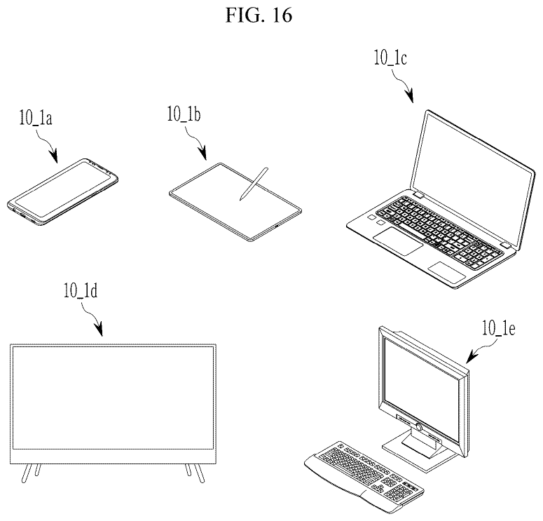

Referring to FIG. 15 to FIG. 18, an electronic device according to an embodiment will be described. FIG. 15 is a block diagram of an electronic device according to an embodiment, and FIGS. 16 to 18 are schematic views of electronic devices according to various suitable embodiments.

Referring to FIG. 15, the electronic device 10_0 according to an embodiment may include a display module 11, a processor 12, a memory 13, and a power module 14. The electronic device 10_0 may further include an input module 15, a non-image output module 16, and/or a communication module 17.

The electronic device 10_0 may output various suitable information in the form of images through the display module 11. When the processor 12 executes an application stored in the memory 13, image information provided by the application may be provided to a user through the display module 11. The power module 14 may include a power supply module such as a power adapter or a battery device, and a power conversion module that converts power supplied by the power supply module to generate power necessary for operation of the electronic device 10_0. The input module 15 may provide input information to the processor 12 and/or the display module 11. The non-image output module 16 may receive non-image information from the processor 12, for example, sound, haptic, and/or light information, and provide it to the user. The communication module 17 is a module to transmit and receive information between the electronic device 10_0 and external devices, and may include a receiver and a transmitter.

At least one of the components of the above-described electronic device 10_0 may be included in the display device according to the above-described embodiments. Also, some of the individual modules that are functionally included in the electronic device 10_0 may be included in the display device, and other parts may be provided separately from the display device. For example, the display device may include the display module 11, and the processor 12, memory 13, and power module 14 may be provided in the form of other devices within the electronic device 10_0 that is not the display device.

FIGS. 16 to 18 illustrate examples of various suitable electronic devices to which the display device according to embodiments is applied.

FIG. 16 illustrates a smartphone 10_1a, a tablet PC 10_1b, a laptop 10_1c, a TV 10_1d, and a desktop monitor 10_1e as examples of electronic devices.

The smartphone 10_1a may include an input module such as a touch sensor and a communication module in addition to the display module. The smartphone 10_1a may process information received through the communication module and/or other input modules to display information through the display module of the display device.

A tablet PC 10_1b, a laptop 10_1c, a TV 10_1d, and a desktop monitor 10_1e may include a display module and an input module similar to a smartphone 10_1a, and may further include a communication module in some cases.

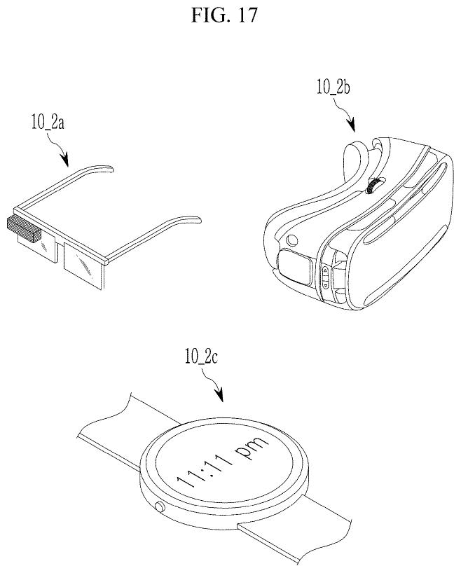

FIG. 17 illustrates an example of an embodiment where an electronic device including a display module is applied to a wearable electronic device. The wearable electronic device may be smart glasses 10_2a, a head-mounted display 10_2b, a smart watch 10_2c, and/or the like.

The smart glasses 10_2a and the head-mounted display 10_2b may include a display module that emits display images and a reflector that reflects the emitted display screen to provide to the user's eyes, and through this, may provide virtual reality and/or augmented reality screens to the user.

The smart watch 10_2c includes a biosensor as an input device, and can provide biometric information recognized through the biosensor to the user through the display module.

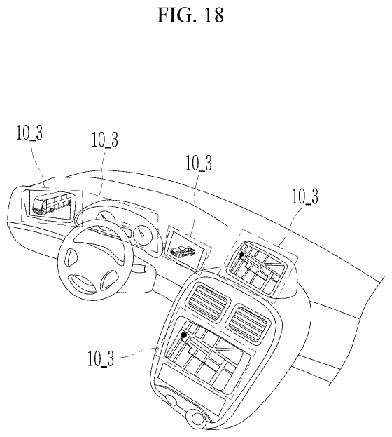

FIG. 18 illustrates an example of an embodiment where an electronic device including a display module is applied to a vehicle. For example, the electronic device 10_3 may be applied to a vehicle instrument panel, a center fascia, and/or may be applied to a CID (Center Information Display) placed on a vehicle dashboard and/or a room mirror display replacing a side mirror.

While the subject matter of this disclosure has been described in connection with what is presently considered to be practical embodiments, it is to be understood that the present disclosure is not limited to the disclosed embodiments. On the contrary, the present disclosure is intended to cover various suitable modifications and equivalent arrangements included within the spirit and scope of the appended claims, and equivalents thereof.

### Description of Symbols

DA, DA1, DA2, DA3: Display Area
1000: Display Device
100: Display Module
10: Display Panel
10a, 10b, 10c: Display Portion
20: Window
20a: Flat Area
20b, 20c: Curved Area
30: Adhesive Member
200: Housing

1 what is claimed is:

1. A window member comprising:
a flat area that extends in a first direction and a second direction and is substantially flat; and
a curved area that extends from the flat area and has a curved shape along a third direction perpendicular to the first direction and the second direction,
wherein the flat area has a first thickness along the third direction, and
the curved area has a second thickness at a first point of the curved area where the thickness direction perpendicular to the tangent line to the outline of the curved area forms a first angle with the third direction, and
the second thickness is smaller than the first thickness.

2. The window member of claim 1, wherein:
the first angle is larger than about 0° and smaller than about 5°.

3. The window member of claim 2, wherein:
the curved area has a third thickness at a second point of the curved area where the thickness direction perpendicular to the tangent line to the outline of the curved area forms a second angle with the third direction, and
the third thickness is larger than the second thickness.

4. The window member of claim 3, wherein:
the second angle is larger than about 75° and smaller than about 90°.

5. The window member of claim 4, wherein:
the thickness of the curved area gradually increases from the first point to the second point.

6. The window member of claim 5, wherein:
the curved area extends along one side of the flat area.

7. The window member of claim 6, wherein:
the third thickness is substantially equal to or smaller than the first thickness.

8. The window member of claim 7, wherein:
the second thickness ranges from about 0.980 times to about 0.999 times the first thickness.

9. The window member of claim 5, wherein:
the curved area is at a corner of the flat area.

10. The window member of claim 9, wherein:
the curved area has a curved shape along the first direction and the second direction.

11. The window member of claim 10, wherein:
the thickness of the curved area measured from a plane perpendicular to the third direction is a minimum thickness at a point where the thickness direction forms a third angle with the first direction, and
the third angle is about 40° to about 50°.

12. A display device comprising:
a display panel that comprises a first display area that extends in a first direction and a second direction, a second display area on a side of the first display area and having a curved shape along a third direction perpendicular to the first direction and the second direction, and a third display area at a corner of the first display area and having a curved shape along the first direction, the second direction, and the third direction;
a window member that comprises a flat area that corresponds to the first display area, a first curved area that corresponds to the second display area, and a second curved area that corresponds to the third display area; and
an adhesive member between the display panel and the window member,
wherein the flat area of the window has a first thickness, and
the second curved area has a second thickness at a first point of the second curved area where the thickness direction perpendicular to the tangent line to the outline of the window forms a first angle with the third direction, and
the second thickness is smaller than the first thickness.

13. The display device of claim 12, wherein:
the first angle is larger than about 0° and smaller than about 5°.

14. The display device of claim 13, wherein:
the second curved area has a third thickness at a second point where the thickness direction forms a second angle with the third direction, and
the third thickness is larger than the second thickness.

15. The display device of claim 14, wherein:
the second angle is larger than about 75° and smaller than about 90°.

16. The display device of claim 15, wherein:
the thickness of the curved area gradually increases from the first point to the second point.

17. An electronic device comprising:
a display module comprising a display device; and
a processor coupled to the display module and configured to control the display module to display an image,
wherein the display device comprises:
a display panel that comprises a first display area that extends in a first direction and a second direction, a second display area on a side of the first display area and having a curved shape along a third direction perpendicular to the first direction and the second direction, and a third display area at a corner of the first display area and having a curved shape along the first direction, the second direction, and the third direction;
a window member that comprises a flat area that corresponds to the first display area, a first curved area that corresponds to the second display area, and a second curved area corresponding to the third display area; and
an adhesive member between the display panel and the window member,
wherein the flat area of the window has a first thickness,
wherein the second curved area has a second thickness at a first point of the second curved area where the thickness direction perpendicular to the tangent line to the outline of the window forms a first angle with the third direction, and
wherein the second thickness is smaller than the first thickness.

18. The electronic device of claim 17, wherein:
the second curved area has a third thickness at a second point where the thickness direction forms a second angle with the third direction, and
the third thickness is larger than the first thickness and the second thickness.

19. The electronic device of claim 18, wherein:
the first angle is larger than about 0° and smaller than about 5° and
the second angle is larger than about 75° and smaller than about 90°.

20. The electronic device of claim 18, wherein:
the thickness of the curved area gradually increases from the first point to the second point.
